(19) United States
(12) Patent Application Publication
(10) Pub. No.: US 2003/0089512 A1
(43) Pub. Date: May 15, 2003

(54) Heat-resistant housing for electrical function elements and use of such a device for a mobile data memory

(75) Inventors: Leopold Faltin, Vienna (AT); Christa Ladanyi, Vienna (AT)

Correspondence Address: SUGHRUE MION, PLLC, 2100 Pennsylvania Avenue, NW, Washington, DC, 20037-3213, US

(73) Assignee: SIEMENS AKTIENGESELLSCHAFT

(21) Appl. No.: 10/260,359

(22) Filed: Oct. 1, 2002

(30) Foreign Application Priority Data
Oct. 1, 2001 (DE) 20116141.9

(51) Int. Cl. H05K 5/00

(52) U.S. Cl. 174/17 SF

(57) ABSTRACT

A heat-resistant housing (G) for electrical function elements (EB) having a receiving chamber (AK) lying as centrally as possible inside it, a cover block (AD), which is sealed with the receiving chamber (AK), and a receiving block (AB), which is inserted into the receiving chamber and encloses the electrical function elements with a material having a temperature-dependent specific thermal capacity, preferably a high-polymer thermoplastic having low density. In the event of a cyclic interplay of heating and cooling phases, a lower stationery temperature results in the receiving block in the proposed structure in comparison to conventional structures, while the overall weight and volume are nonetheless lower. This is achieved by the high-polymer thermoplastic in the receiving block, which increasingly melts as the temperature rises. The large thermal capacity resulting therefrom acts like a heat sink. The heat-resistant housing for the electrical function elements may furthermore be a mobile data memory having a transponder circuit for inductive data exchange.

The following disclosure is based on German Patent Application No. 20116141.9, filed on Oct. 1, 2001, which is incorporated into this application by reference.

### FIELD OF AND BACKGROUND OF THE INVENTION

A hermetically sealed, temperature-resistant data memory device is known from German Patent Application 92 05 049.2. The inside of the housing of this device is almost completely filled with thermal insulator, except for a cavity. The electrical function elements of the device, particularly data memory and power supply elements, are inserted into this cavity.

In an arrangement of this type, the problem occurs that almost completely filling the inside of the housing, except for the cavity, with the thermal insulator causes a relatively large overall volume of the entire housing. Due to this, the ability to handle the device is restricted.

An essential problem of this known device, however, is that—while the thermal insulator delays the penetration of heat into the cavity containing the electrical function elements in the event the housing is strongly heated from the outside—in a subsequent cooling phase of the device, the heat dissipates from the cavity again with the same delay. If a device of this type is subjected to a cyclic interplay of heating and cooling phases, as is the case, for example, when these types of data carriers are used in enameling devices for vehicle bodies in the automobile industry, then a relatively high stationary temperature results inside the cavity. Due to this, the service life of data memory and power supply elements located in the device may be restricted.

### OBJECTS OF THE INVENTION

One object of the present invention is to provide a heat-resistant housing for electrical function elements which is capable of being subjected to a cycle of sequential heating and cooling and which, in spite of comparatively smaller external dimensions and a reduced overall volume and weight, provides a lower stationary temperature for the electrical function elements lying inside it.

A further object is providing a use of such a device for a data memory, particularly a mobile data memory.

### SUMMARY OF THE INVENTION

These and other objects are achieved, according to one formulation of the invention, with a heat-resistant housing for electrical function elements that has an insulating body having a receiving chamber, a cover block configured to seal with the receiving chamber, and a receiving block which is inserted into the receiving chamber and encloses the electrical function elements with a material having a temperature-dependent specific thermal capacity.

This housing has an insulating body which has a receiving chamber as centrally as possible inside it. The receiving chamber is sealed using a cover block. Furthermore, the heat-resistant housing has a receiving block which is introduced into the receiving chamber and encloses the electrical function elements with a material having a temperature-dependent specific thermal capacity. The material may also have significantly elevated values of the specific thermal capacity in a given temperature range (FIG. 3). In this case, the temperature range may be as much as multiple tens of degrees Celsius and begin from a temperature of approximately 90° C. The material having the temperature-dependent specific thermal capacity may, for example, be a high-polymer thermoelastic plastic having a low density, preferably an LDPE plastic.

The insulating body and/or the receiving block may have a cylindrical shape, the ratio of surface to volume preferably being as small as possible (FIGS. 1, 2). Furthermore, the insulating body may be enclosed by a capsule, so that it is hermetically sealed. The capsule is preferably made of a shock-resistant and heat-resistant plastic. Finally, it is possible to manufacture the cover block for sealing the receiving chamber from the same material as the insulating body.

The device may be used as a mobile data memory, particularly for electrical function elements such as memory components and a transponder circuit for data exchange using induction.

The present invention is distinguished in that the electrical function elements embedded in the receiving block are enclosed as uniformly as possible in all spatial directions by a material which has a high specific thermal capacity and good thermal conductivity at a low specific weight. The high specific thermal capacity is achievable by a material having energy-intensive phase transitions such as melting and solidifying in the event of heating and cooling within a specific temperature range. The material therefore has an “indefinite” melting point, i.e., a melting point distributed over a temperature range. The receiving block is further enclosed by an insulating body made of a material having low thermal conductivity and low specific thermal capacity.

The embedding of the electrical function elements achieved in this way has the particular advantage, in the event of cyclic interplay of heating and cooling phases, that, in comparison to a single-layer, complete enveloping using thermal insulation, a lower stationary temperature results in the region of the electrical function elements due to the enclosing receiving block. While, of course, the insulating body delays the penetration of heat to the electrical function elements, the material of the receiving block, which has a large thermal capacity and good thermal conductivity, acts like a heat sink in this case.

A further advantage of the arrangement according to the present invention is that, through the combination of an external insulating body with an internal receiving block, and its material properties, the external dimensions and the weight of a housing of this type for electrical function elements may be significantly reduced in comparison to the prior art. The wall thickness of the insulating body, in particular, may be greatly reduced.

### BRIEF DESCRIPTION OF THE DRAWINGS

The invention is described in more detail with reference to the following figures, which illustrate preferred embodiments and associated advantages.

FIGS. 1 and 2: show an exemplary embodiment of the heat-resistant housing according to the present invention, inside of which a receiving block for electrical function elements is positioned symmetrically to the radial axis and is sealable using a circular cover block,

FIG. 3: shows a typical trace of the specific thermal capacity of an LDPE thermoplastic as a function of the temperature and as an exemplary material having high specific thermal capacity according to the present invention, and

FIG. 4: shows an exemplary use of the heat-resistant housing as a mobile data memory, which, as an example of electrical function elements, has a circuit board equipped with components and an antenna ring connected thereto.

### DETAILED DESCRIPTION OF THE PREFERRED EMBODIMENTS

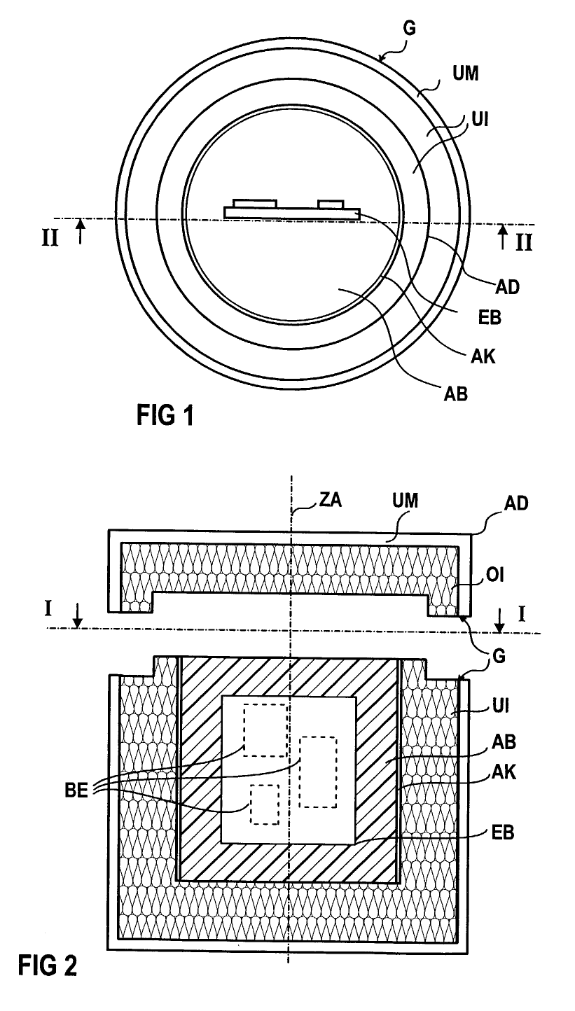

FIGS. 1 and 2 show an exemplary embodiment of heat-resistant housing G, according to the present invention, inside of which a receiving block AB for electrical function elements EB is positioned symmetrically to a radial axis ZA and is sealable using a circular cover block AD.

FIG. 1 shows exemplary heat-resistant housing G in a top view. In a preferred embodiment according to the present invention, this housing has a cylindrical shape with a central, radial axis of symmetry ZA. Furthermore, inside the housing, a receiving chamber AK, into which a cylindrical receiving block AB, which fits therein, for electrical function elements EB is inserted, is positioned symmetrically to the axis of symmetry ZA. The cylindrical receiving chamber AK is enclosed as well by a cylindrical insulating body UI, OI having a low thermal conductivity according to the present invention. A suitable material for insulating body UI, OI may, for example, be a thermal insulator, insulating foam, glass wool, or even a heat-resistant light fleece, also having low thermal capacity. Components BE of electrical function elements EB to be thermally protected may be positioned centrally inside the receiving block on a circuit board, for example. Function elements EB may, for example, be a transponder circuit, a sensor, or an energy store such as a battery or an accumulator.

One advantage of this design is that the electrical function elements EB inserted into the receiving chamber AK are enclosed nearly uniformly in all radial spatial directions by the material of receiving block AB and by the material of insulating body UI, OI, which encloses the receiving block AB.

The exemplary housing G shown in FIGS. 1-2 additionally has a heat-resistant capsule UM, which encloses housing G for an advantageous mechanical protection according to the present invention. Capsule UM may be made from a shock-resistant, heat-resistant plastic, for example.

According to the present invention, receiving block AB in FIG. 1 is made of a material having a temperature-dependent specific thermal capacity and which uniformly encloses electrical function elements EB. This is particularly clear in the cross-sectional illustration of FIG. 2 along section line II-II in FIG. 1. The enclosing material may be, for example, a plastic, particularly a high-polymer thermoelastic LDPE plastic. A plastic of this type has, in a specific temperature range, significantly elevated values for the specific thermal capacity (J/Kg*K) in comparison to metals or low-molecular materials.

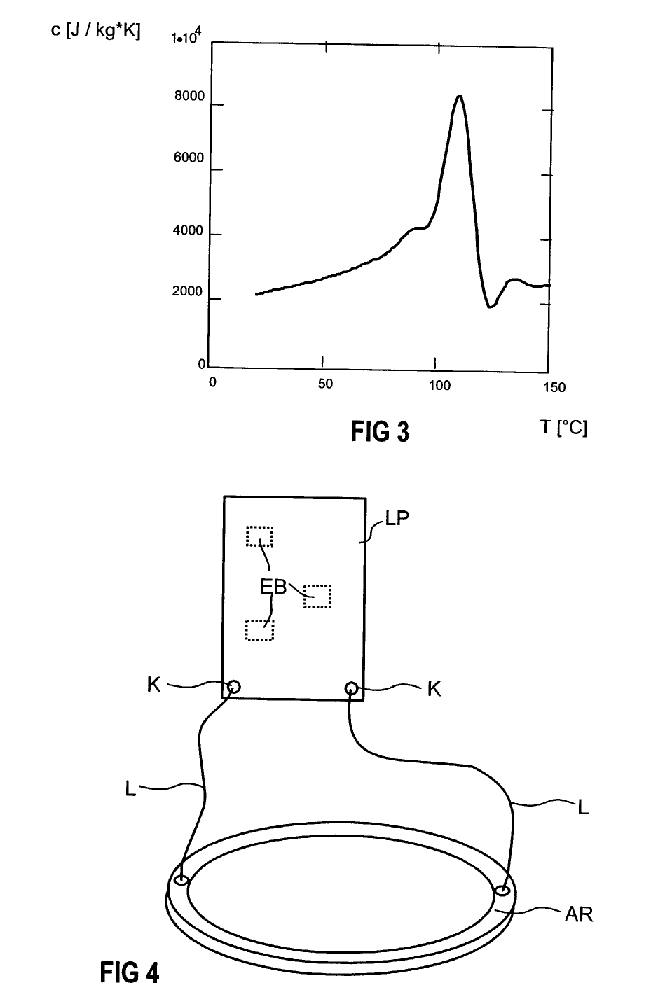

In FIG. 3, an exemplary trace of the specific thermal capacity as a function of the temperature for an LDPE plastic is shown for better comprehension. In this case, this plastic has significantly elevated values for the specific thermal capacity in the temperature range from approximately 90° C. to 110° C. The reason for this is phase transitions, particularly melting processes occurring distributed within this temperature range, for which a high melting energy must be provided from the plastic. Due to these “distributed” melting procedures, the exemplary plastic does not pass into the liquid aggregate state at a punctual melting point. Instead, the entire plastic becomes softer with increasing temperature. Above a certain temperature, even the exemplary thermoplastic becomes liquid.

An associated advantage is that, for a cyclic interplay of heating and cooling phases, a lower stationary temperature is achieved in the region of the electrical function elements EB, in comparison to a single-layer, complete enveloping using a thermal insulator, due to the presence of the enclosing receiving block AB. This is advantageously achieved through the use of the receiving block AB having temperature-dependent specific thermal capacity, particularly a high-polymer LDPE thermoplastic.

The exemplary high-polymer LDPE thermoplastic has the further advantage that it has a low specific weight and a large thermal capacity with good thermal conductivity. In this way, the overall weight of heat-resistant housing G is advantageously reduced, particularly when using a suitable combination of external insulating body UI, OI and the internal receiving block AB with its material properties. While, of course, insulating body UI, OI delays the penetration of heat to electrical function elements EB, in this case, the material of receiving block AB, which has a large thermal capacity and good thermal conductivity, acts like a heat sink.

By selecting a plastic of, for example, the LDPE type, the further advantageous effect may be achieved that, in the event heat acts on housing G, such as in enameling devices, the maximum permissible operating temperature of approximately 120° C. for electrical function elements EB, such as semiconductor components or energy stores, is reached only after a very long time.

Due to this it is, for example, also advantageously possible to immerse electrical function elements EB in a receptacle having the exemplary liquid plastic, the receptacle to correspond approximately to the external shape of receiving chamber AK. After cooling, the electrical function elements are then, for good thermal transmission, completely solidly enclosed with the plastic according to the present invention. Receiving block AB arising in this way may then advantageously be inserted easily into the receiving chamber AK provided therefor.

Furthermore, according to the present invention, the ratio of surface to the respective enclosed volume of the cylindrical insulating body UI, OI and of the receiving block AB may be as low as possible. FIGS. 1 and 2 show this advantageously for exemplary housing G, in which the height and the diameter are equal. In this way, the thermally active surface can be reduced e.g. for a given volume, and the dwell time in the heating phase may be increased further.

Furthermore, the housing G for electrical function elements EB illustrated in FIGS. 1 and 2 is advantageously implemented as two parts. In this case, insulating body UI, OI is separated into an upper part OI and a lower part UI. When the two parts are placed on top of one another, two complementary toothed rings advantageously engage in one another, as is illustrated in longitudinal section I-I of FIG. 2. In this way, a continuous insulating effect of two-part insulating body UI, OI is ensured. In the two-part embodiment of insulating body UI, OI shown in FIGS. 1, 2, both the upper part OI and the lower part UI are enclosed by a half-shell capsule. The half shells may in turn be connected to one another in the toothed region at the outer sides of the engaged toothed rings in such a way that the heat-resistant housing G is hermetically sealed.

Finally, FIG. 4 illustrates an exemplary use of the heat-resistant housing G as a mobile data memory, which has a circuit board LP, equipped with components BE as an example of electrical function elements EB, and an antenna ring AR connectable thereto. In this case, FIG. 4 shows an example of a circuit board LP, which carries function elements EB of the mobile data memory device illustrated for exemplary purposes. These are memory elements and circuit parts, with which new data may be received from external sources and entered into the memory elements, and/or the content of the memory elements may be transmitted as needed, preferably in a contactless, inductive manner. These types of circuit parts are generally referred to as a transponders.

In this case, an antenna ring AR is connected via lines L to contacts K of circuit board LP. The memory elements located on circuit board LP may, in particular, exchange data in contactless, inductive ways with external read/write devices via antenna ring AR. Antenna ring AR may advantageously be laid directly on the outside of upper part OI or lower part UI of the insulating body shown in FIGS. 1, 2. In the encapsulated embodiment, it preferably lies exactly in the space between the inside of the capsule bottom and the outside of one of the two parts OI, UI of insulating body.

The above description of the preferred embodiments has been given by way of example. From the disclosure given, those skilled in the art will not only understand the present invention and its attendant advantages, but will also find apparent various changes and modifications to the structures, methods and uses disclosed. It is sought, therefore, to cover all such changes and modifications as fall within the spirit and scope of the invention, as defined by the appended claims, and equivalents thereof.

What is claimed is:

1. A heat-resistant housing for electrical function elements, comprising:
an insulating body which has a receiving chamber,
a cover block configured to seal with the receiving chamber, and
a receiving block which is inserted into the receiving chamber and encloses the electrical function elements with a material having a temperature-dependent specific thermal capacity.

2. The housing according to claim 1, wherein the receiving chamber is central within the insulating body.

3. The housing according to claim 1, wherein the material having the temperature-dependent specific thermal capacity has significantly elevated values within a given temperature range.

4. The housing according to claim 3, wherein the temperature range is at least ten degrees Celsius.

5. The housing according to claim 3, wherein the temperature range begins from a temperature of approximately 90° C.

6. The housing according to claim 1, wherein the material having the temperature-dependent specific thermal capacity is a high-polymer thermoelastic plastic having low density.

7. The housing according to claim 6, wherein the high-polymer thermoelastic plastic is an LDPE type plastic.

8. The housing according to claim 1, wherein the insulating body has a cylindrical shape.

9. The housing according to claim 1, wherein the receiving block has a cylindrical shape.

10. The housing according to claim 8, wherein the housing has a smallest possible ratio of surface to volume.

11. The housing according to claim 1, wherein the insulating body is enclosed by a capsule hermetically sealing the insulating body.

12. The housing according to claim 11, wherein the capsule is made of a shock-resistant, heat-resistant plastic.

13. The housing according to claim 1, wherein the cover block is made of the same material as the insulating body.

14. A data memory comprising:
electrical function elements; and
a heat-resistant housing comprising:
an insulating body which has a receiving chamber,
a cover block configured to seal with the receiving chamber, and
a receiving block which is inserted into the receiving chamber and encloses the electrical function elements with a material having a temperature-dependent specific thermal capacity.

15. The data memory according to claim 14, wherein the data memory is a mobile data memory:

16. The data memory according to claim 14, wherein the electrical function elements comprise at least one of memory components and a transponder circuit.

17. A device comprising:
at least one electrical element;
a material having melting points distributed over a range of temperatures and embedding the electrical element in all spatial directions; and
an insulating body of low thermal conductivity and low specific thermal capacity enclosing the material.

18. The device according to claim 17, wherein the material and the insulating body are substantially cylindrical in shape.

19. The device according to claim 17, further comprising a capsule of shock-resistant and heat-resistant plastic.
